(19) United States
(12) Patent Application Publication
(10) Pub. No.: US 2024/0234158 A1
(43) Pub. Date: Jul. 11, 2024

(54) Method for Etching Features in a Layer in a Substrate

(71) Applicant: Tokyo Electron Limited, Tokyo (JP)

(72) Inventors: Indroneil Roy, Albany, NY (US); Jason Marion, Albany, NY (US); Yusuke Yoshida, Albany, NY (US); Yun Han, Albany, NY (US); Aelan Mosden, Albany, NY (US); Ken Kobayashi, Miyagi (JP)

(21) Appl. No.: 18/151,223

(22) Filed: Jan. 6, 2023

(51) Int. Cl. H01L 21/3065; H01J 37/32; H01L 21/02; H01L 21/311

(52) U.S. Cl. CPC H01L 21/30655; H01J 37/32816; H01L 21/02274; H01L 21/31116; H01L 21/31144; H01J 2237/3345; H01J 2237/3347

(57) ABSTRACT

A method for fabricating a semiconductor device includes forming a pattern of trenches by etching a first layer formed over an underlying layer of a substrate, each of the trenches having an aspect ratio (AR) in a range with a lower limit of a first AR and an upper limit of a second AR, the pattern including a low-AR trench having the first AR and a high-AR trench having the second AR, the AR of a trench being a ratio of its depth to its opening width, the etching including: executing a first recipe in a plasma chamber to anisotropically etch the first layer for a first duration by flowing etchants through the chamber, an etch rate of the first layer being higher on the low-AR trench relative to that on the high-AR trench; and after executing the first recipe, executing a second recipe in the plasma chamber to etch the first layer anisotropically and concurrently deposit oxygen-containing etch byproducts to passivate exposed portions of sides of the trenches, the etch rate of the first layer being lower on the low-AR trench relative to that on the high-AR trench, wherein executing the second recipe increases a relative oxygen content in the plasma chamber from a first value during the executing of the first recipe to a second value.

### TECHNICAL FIELD

The present invention relates generally to a method for fabricating a semiconductor device, and, in particular embodiments, to a method for etching features in a layer in a substrate.

### BACKGROUND

An integrated circuit (IC) is a network of electronic components built by sequentially depositing and patterning layers of various materials to form a monolithic structure over a semiconductor substrate. At each patterning level, a radiation pattern is transferred to a resist layer coated on the substrate using lithography techniques. The patterned resist serves as a mask to etch an underlying layer used directly to construct structures of electronic components or to memorize the pattern on a hardmask used in a subsequent pattern transfer etch. An etch pattern is typically defined by trenches in a masking layer. The pattern etched through the etch pattern may be viewed as lines separated by trenches or trenches separated by lines, depending on the specific component for which the structure is formed. For example, transistor fins etched in a silicon layer are viewed as lines separated by trenches, later filled with oxide, whereas grooves for wires etched in an oxide layer are viewed as trenches separated by the oxide, where the trenches are later filled with metals. In either case, the pattern layout may have diverse geometries, including trenches with narrow and wide openings, and the processing (usually anisotropic plasma etching) is expected to yield vertical sides free of notch and foot defects and a fixed depth for trenches of all aspect ratios formed in one pattern. This becomes increasingly difficult as continued scaling of lateral dimensions pushes trench openings down toward 10 nm, hence expanding the range of aspect ratios of trenches. With plasma technology thus challenged to concurrently etch a low aspect ratio trench and a high aspect ratio trench with ideal side profiles, further innovation is desired.

### SUMMARY

A method for fabricating a semiconductor device, the method including: forming a pattern of trenches by etching a first layer formed over an underlying layer of a substrate, each of the trenches having an aspect ratio (AR) in a range with a lower limit of a first AR and an upper limit of a second AR, the pattern including a low-AR trench having the first AR and a high-AR trench having the second AR, the AR of a trench being a ratio of its depth to its opening width, the etching including: executing a first recipe in a plasma chamber to anisotropically etch the first layer for a first duration by flowing etchants through the chamber, an etch rate of the first layer being higher on the low-AR trench relative to that on the high-AR trench; and after executing the first recipe, executing a second recipe in the plasma chamber to etch the first layer anisotropically and concurrently deposit oxygen-containing etch byproducts to passivate exposed portions of sides of the trenches, the etch rate of the first layer being lower on the low-AR trench relative to that on the high-AR trench, wherein executing the second recipe increases a relative oxygen content in the plasma chamber from a first value during the executing of the first recipe to a second value.

A method for fabricating a semiconductor device, the method including: in a plasma chamber, anisotropically etching a silicon layer formed over an underlying layer of a substrate through an etch mask to form features having a plurality of sides with vertical side profiles, the plurality of sides including a first side with a first aspect ratio (AR) and a second side with a second AR higher than the first AR, the etching including: forming an upper portion of the features by exposing the substrate, for a first duration, to plasma generated using chlorine, hydrogen bromide, oxygen, and an inert gas; and at the end of the first duration, performing, for a second duration, an aspect ratio dependent passivation (ARDP) while etching the silicon layer, the etching of the silicon layer during the second duration being slower on the first side than on the second side, the performing including reducing a chamber pressure, reducing a ratio of a flow rate of etchants to a flow rate of oxygen, the etchants being chlorine and hydrogen bromide, and, where, during the performing, oxygen-containing etch byproducts are deposited to passivate exposed portions of the sides, the deposition being faster on the first side than on the second side.

A method for forming a pattern of features in a first layer of a substrate, the method including: forming, over the first layer, an etch mask having a two-dimensional (2D) layout geometrically identical to the pattern of features, the features being separated from each other by one of a plurality of trenches, the plurality of trenches including a low aspect ratio (low-AR) trench and a high aspect ratio (high-AR) trench; using the etch mask, anisotropically etching an upper portion of the first layer for a first duration to form upper portions of the features and the plurality of trenches, the first duration being configured to expose a portion of a surface of an underlying layer at the bottom of the low-AR trench, the underlying layer being disposed adjacent below the first layer; and performing, over a passivation duration, an aspect ratio dependent passivation

(ARDP) while anisotropically etching a lower portion of the first layer, the passivation being faster in the low-AR trench relative to the high-AR trench, the etching of the lower portion of the first layer being slower in the low-AR trench relative to the high-AR trench, the passivation duration being configured to form a vertical side profile proximate a base of the low-AR trench and to expose a portion of a surface of the underlying layer at the bottom of the high-AR trench.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B compare cross-sectional views of substrates having the same pattern of features, the view in FIG. 1A is for an etch process without aspect-ratio dependent passivation

(ARDP) and the view in FIG. 1B is for an etch process with ARDP, in accordance with some embodiment;

FIG. 2 illustrates a flowchart describing a method for patterning a layer with a plasma etch process that comprises concurrent ARDP and anisotropic etching, in accordance with some embodiment; and

FIGS. 3-6 illustrate various cross-sectional views of a substrate at intermediate stages of processing using the method described in the flowchart illustrated in FIG. 2.

### DETAILED DESCRIPTION OF ILLUSTRATIVE EMBODIMENTS

The disclosure describes embodiments of a method for etching a pattern in a layer of a substrate to form trenches over a wide range of trench openings. The aspect ratio (AR) of a trench being a ratio of a trench depth to the trench opening, this implies that the trenches have a wide range of ARs. As noted in the background section, a pattern of features separated by trenches may be equivalently viewed as a pattern of trenches.

It may be difficult to fabricate, in the same pattern, a low-AR trench and a high-AR trench to have the same depth and near ideal surfaces, i.e., a flat bottom surface and vertical sides with no foot or notch defects using conventional anisotropic plasma etching, for example, using single step reactive ion etching (RIE). The difficulty occurs because the supply of etchants at the trench bottom (the surface from which material is to be removed) depends on the trench AR. As the bottom gets deeper with etching, the etchant density in a narrow trench drops relative to the etchant density in a wide trench.

In an RIE process, the etchants are energetic ions and neutral radicals that interact physically and chemically to etch an exposed surface. As the etching progresses, it becomes increasingly difficult to transport the charge neutral radicals down to reach the bottom of a trench and react with the surface there, particularly in a trench with a small opening. The ions may be directed by a vertical electric field toward the bottom surface. Nevertheless, all ions are not moving vertically downwards; because of random collisions, ions move in directions distributed randomly around the vertical. Hence, some of the ions collide with the sides of the trench and lose energy prior to reaching the bottom of the trench. These effects diminish the etch rate in the narrow high-AR trench relative to a wide low-AR trench, a phenomenon known as microloading, RIE lag, or aspect ratio dependent etching (ARDE). The impact of ARDE on the structure of the trenches may depend on the specific application, as explained further below.

The effect of ARDE may preclude conventional plasma etch processes from providing an adequate process window with acceptably low foot and notch defects over a wide range of ARs of trenches. The minimum AR may be 0.15, and the maximum AR may be 15. With the advent of extreme ultraviolet (EUV) lithography, the trench opening is scaled down to a regime where footing and notching of even a few nanometers may not be tolerable. The trenches may have openings in a range defined by a minimum opening, sₘᵢₙ, and a maximum opening, sₘₐₓ, or, equivalently, the trenches may have ARs in a range defined by a lower limit of a first AR equal to h/sₘₐₓ and an upper limit of a second AR equal to h/sₘᵢₙ. Here, h is a vertical height of the trenches and is assumed to be roughly the same for narrow and wide trenches. The use of ARDP during etching trenches is advantageous for fabricating IC designs that have a relatively wide range of aspect ratios, including IC designs where the first AR may be higher than 0.15, but not more than 3, and, likewise, the second AR may be less than 15, but not less than 5. If the aspect ratios of trenches in an IC design fall in a narrow range then conventional anisotropic plasma etching may suffice. For the example embodiments described in this disclosure, sₘᵢₙ may be between 10 nm and 30 nm and sₘₐₓ may be greater than 500 nm and less than 3 μm. In various embodiments, sₘₐₓ may be between 16 times to 100 times sₘᵢₙ. Generally, in order to maintain adequate electrical performance, the vertical dimension, h, may not reduce as aggressively as sₘᵢₙ. For, sₘᵢₙbetween 10 nm and 30 nm, h may be greater than 150 nm and less than 450 nm. In the example embodiments, the patterns of features and trenches include a low-AR trench having the first AR and a high-AR trench having the second AR, where the second AR may be between 16 times to 100 times the first AR.

The embodiments of a method for etching a pattern of trenches with a wide range of aspect ratios utilizes an aspect-ratio dependent passivation (ARDP) applied concurrently with anisotropic plasma etching. Conventional anisotropic plasma etching is performed without applying ARDP. When ARDP is applied concurrently with anisotropic plasma etching, etch rate decreases with increasing trench opening. In contrast, as explained above, for conventional anisotropic plasma etching, etch rate increases with increasing trench opening, a phenomenon referred to as ARDE. Thus, a multi-step etch process that includes a step where ARDP is applied may be used to counter the effects of ARDE from steps, where ARDP is not applied. The invented method for etching a pattern of trenches with low-AR (wide) and high-AR (narrow) trenches with suppressed ARDE effects is to utilize such a multi-step plasma etch process. Accordingly, the example embodiments are multi-step plasma etch processes that incorporate a duration for which the concurrent ARDP and anisotropic etching is applied.

The ARDP is achieved by altering plasma etch process parameters such as relative flow rates and pressure of gases in a gaseous mixture in the plasma chamber to promote sidewall passivation by deposition of etch byproducts on exposed sides of trenches. As explained in further detail below, the timing parameters for ARDP, in conjunction with timing parameters of other steps of the multi-step etch process, may be configured to achieve a desired vertical side profile and depth, for the low-AR trench as well as the high-AR trench included in the pattern of trenches. The timing parameters for ARDP comprises the juncture at which ARDP is applied and the duration over which the concurrent ARDP and etching is performed. The multi-step etch process, with the ARDP, is described by an example embodiment, where features are etched in a layer formed over an underlying layer of a substrate. Use of the embodiments described in this disclosure provides an advantage of patterning, in a layer of a substrate, features with near vertical sides, devoid of notch and foot defects, both in regions with densely packed features and in regions with sparsely packed or isolated features.

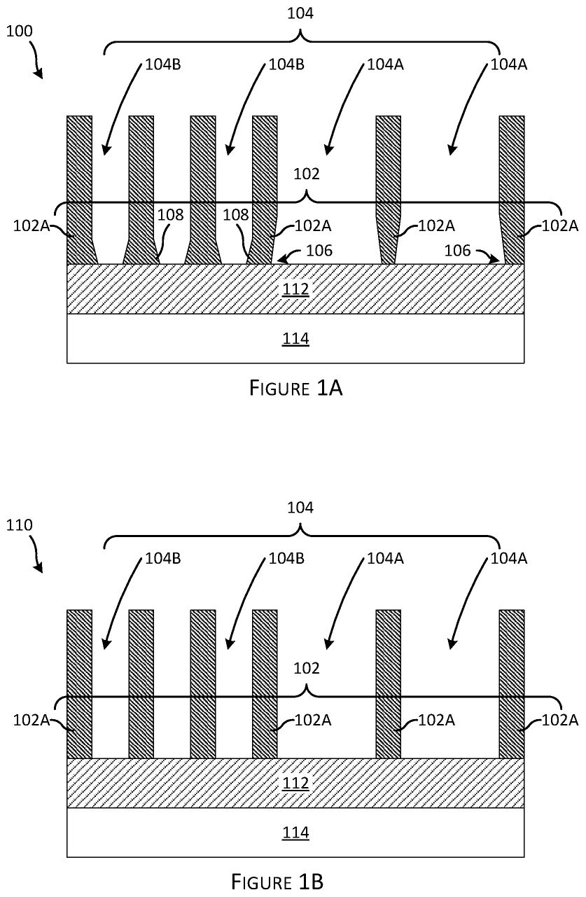

FIGS. 1A and 1B compare cross-sectional views of a substrate 100 with another substrate 110 having the same pattern of features 102 etched into a layer, where the layer in substrate 100 has been etched without applying ARDP during the etching (FIG. 1A) and the layer in substrate 110 has been etched using a multi-step etch process that includes a step where ARDP is applied during anisotropic etching (FIG. 1B). A pattern of trenches 104 separates each feature 102A of the pattern of features 102 from other features 102A. The pattern of trenches 104 comprises low-AR trenches 104A and high-AR trenches 104B. An underlying layer 112 is seen below the layer having the pattern of features 102. All layers of the substrates 100 and 110 below the underlying layer 112 are collectively shown as a base layer 114. The etch process has stopped on the underlying layer 112. So, the bottom surface of each trench of the pattern of trenches 104 is an exposed portion of a surface of the underlying layer 112.

As explained above, because the etch process used to form the structure illustrated in FIG. 1A uses conventional anisotropic plasma etching, it exhibits ARDE. An effect of ARDE (that is not compensated with ARDP) is that the pattern of trenches 104 shows notch defects 106 and foot defects 108, as understood from the following explanation.

For the conventional anisotropic plasma etch process (FIG. 1A), the sides of the high-AR trenches 104B could be straightened out by increasing the etch duration to remove the foot defects 108 seen in FIG. 1A, but that would exacerbate the notch defects 106 in the sides of the low-AR trenches 104A. Likewise, by reducing the etch duration, it may be possible to suppress the notch defects 106 seen in FIG. 1A. However, that increases the size of the foot defects 108 and entails the risk of incomplete separation of the features 102A that are in the densely packed region if the underlying layer 112 remains completely covered at the bottom of the narrow high-AR trenches 104B. If the range of aspect ratios is wide then there may not be sufficient process window for the conventional anisotropic plasma etch process to be manufacturable.

As illustrated in FIG. 1B, the etch process used to form the structure illustrated in FIG. 1B has eliminated the notch defects 106 (seen in the sides of the low-AR trenches 104A in FIG. 1A) and the foot defects 108 (seen on the sides of the high-AR trenches 104B in FIG. 1A). This may be achieved by counterbalancing ARDE with ARDP using a multi-step etch process that includes a step where ARDP is applied during anisotropic etching.

As described in this disclosure, the layer is patterned using an anisotropic plasma etch process comprising a sequence of etch steps performed in situ in a plasma chamber. The sequence includes a step during which, while the trenches are being etched, some of the etch byproducts are deposited on exposed surfaces of trenches. The deposition partially passivates the surfaces, thereby slowing down the etch rate in the areas on which the byproducts get attached. In some embodiments, where the layer being etched comprises silicon and the plasma comprises oxygen radicals, silicon oxide may also be deposited on exposed surfaces of trenches. The process parameters are adjusted such that the etch byproducts deposit preferentially in a trench with a wide opening (i.e., a low-AR trench) relative to a narrow trench (i.e., a high-AR trench). Because the passivation of the sides depends on the aspect ratio of the trench, this passivation technique is referred to as an aspect-ratio dependent passivation (ARDP). It is noted that, passivating with etch byproducts occurs concurrently with anisotropic etching. One characteristic of the disclosed etch processes is that, in etching with ARDP applied, the passivation rate increases with increasing trench opening and, because of the higher passivation rate in wider trenches, the anisotropic etch rate decreases with increasing trench opening.

The process parameters and materials may be selected such that, when the ARDP is applied, the passivation is predominant in the low-AR trench to arrest material removal, while passivation in the high-AR trench is much less, hence, has little effect in slowing down the etch rate. The selection of process parameter values to adjust the passivation and removal rates in etching with ARDP applied, and the selection of the timing parameters for initiating and terminating the steps that perform etching with ARDP applied may depend on various factors, such as h, sₘᵢₙ, sₘₐₓ, and the composition of materials exposed to plasma. For example, in an example embodiment, the layer being etched may be a silicon-based material, the etchants may comprise Cl₂ and HBr, and O₂ may be included in the gaseous mixture to form passivating byproducts that are materials containing O₂ and Si, in combination with H, Br, and/or Cl. The process parameters would then include the flow rates of Cl₂, HBr, and O₂.

The applications for the invented method may be in two broad categories; a first category, where the material removal terminates on a roughly planar underlying layer (e.g., the underlying layer 112) and a second category where, at the end of the material removal, the bottom surfaces of the trenches are within the layer being etched. The example embodiments described in this disclosure fall in the first category.

In an application where the trenches do not extend through the layer being etched to expose an underlying layer or an etch-stop layer, ARDE may result in nonuniform trench depth. For example, trenches in an interlayer dielectric (ILD) layer intended for metal lines may be formed using a timed etch in order to avoid the extra processing cost of depositing an etch stop layer at a desired depth in the ILD layer. If the layout of the pattern of trenches includes narrow and wide trenches then, due to ARDE, a low-AR trench is likely to be deeper than a high-AR trench. Additionally, a bottom surface of the trenches may acquire a U-shape because of a higher flux of radicals along a central region of the trench relative to the flux along the periphery. Another example of a geometry dependent effect of ARDE, in trenches extending partially into the layer being etched, is a gradual deepening of a narrow trench along its length, observed, near a location where one end of the narrow trench opens into a side of a wide trench. An extra supply of radicals from the wide trench boosts the etch rate in the narrow trench for a distance close to the junction, causing its bottom surface to dip gradually toward the end.

In contrast, the trench depth is uniformly fixed to be equal to a thickness of the layer being etched when the trenches are formed extending vertically through the layer being etched and stopping on an exposed surface of an underlying layer by using a selective etch chemistry. Generally, in such an application, a pattern of features are formed by etching; the trenches isolating each of the features from its neighbors. A height, h, of sides of features is same as the trench depth, the sides of trenches being the sides of features. Since h is same as the thickness of the layer being etched, uniformity of h depends largely on the thickness uniformity achieved by the deposition process used in forming that layer instead of the etch process used in patterning the layer. Likewise, a flatness of the bottom surface of the trench, is insensitive to the etch process, being determined by a planarity of a top surface the underlying layer. Nevertheless, ARDE may cause difficulty in achieving uniformly vertical side profiles of the etched features and trenches.

The sides of the trenches may have notch and foot defects proximate a base of the sides of trenches. Because of ARDE, the low-AR trench is etched faster to reveal the underlying layer at the bottom, while the underlying layer below the high-AR trench is still covered by the layer being etched. Hence, the anisotropic etching has to be continued to remove more material from the high-AR trench. But, during this time, the sides of the low-AR trench remain exposed to etchants and, although the plasma is biased to be highly anisotropic, a portion of the sides of the wide trench proximate its base may get etched laterally, resulting in notches along the sides of features, as known to persons skilled in the art. The longer the etching continues, the worse is the notch defect.

In the high-AR trench, the progression of etching exposes the underlying layer below. The central region is exposed first because, as mentioned above, the radical flux is, generally, higher nearer the center relative to the edges. This implies that the side profiles proximate the bases of features separated by the high-AR trench has a foot extending from the edges toward the center. Further etching opens up the exposed central region further by reducing the extent of the undesired foot in the high-AR trench, but, as mentioned above, extending the etching time beyond clearing the bottom of the low-AR trench increases the undesired notch in the low-AR trench. Thus, there is a tradeoff between the severity of the foot defect and the severity of the notch defect.

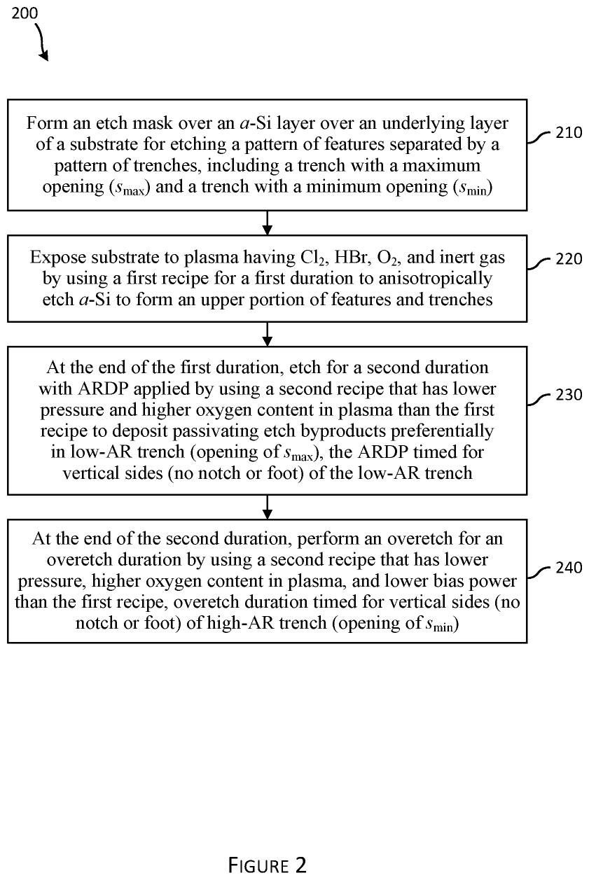

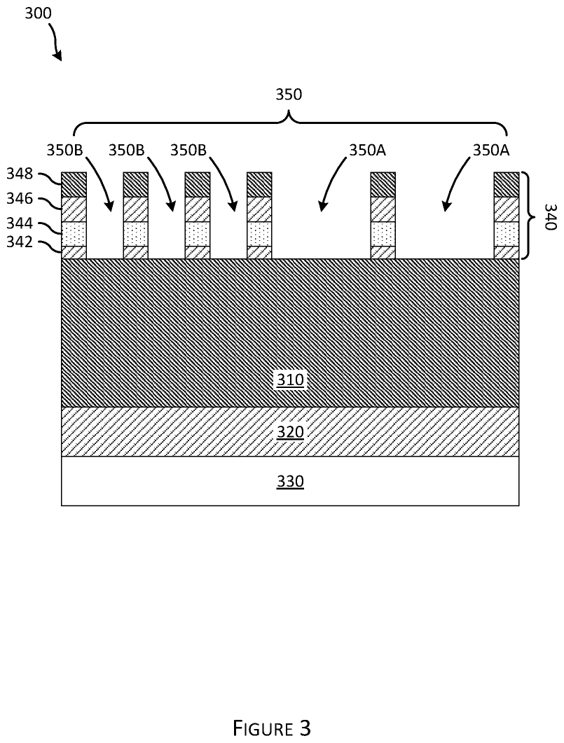

An example embodiment of a method 200 for patterning a layer with a multi-step plasma etch process, which incorporates concurrent ARDP and anisotropic etching step to counter ARDE effects from a conventional anisotropic etch step, is described with reference to a flowchart illustrated in FIG. 2 and various cross-sectional views of a substrate 300 at intermediate stages of processing illustrated in FIGS. 3-6. The patterning results in forming features separated by trenches, with trench openings distributed over a range having a minimum opening, sₘᵢₙ, and a maximum opening, sₘₐₓ.

As illustrated in FIG. 3 and indicated in box 210 of the method 200 in the flowchart illustrated in FIG. 2, in the example embodiment, the layer to be etched is an amorphous silicon (α-Si) layer 310 formed over an underlying layer 320 comprising silicon oxide. A base layer 330 represents all layers of the substrate 300 below the underlying layer 320. As described in further detail below, a pattern of features is formed by etching through the α-Si layer 310 to expose the underlying layer 320, thus separating out the features by a pattern of trenches in the α-Si layer 310.

A patterned etch mask 340 is formed over the a-Si layer 310, as indicated in box 210 in FIG. 2. As illustrated in FIG. 3, the etch mask 340 in the example embodiment is a stack of four hardmask layers. A first hardmask layer 342 comprising a silicon oxide pad layer is formed over the α-Si layer 310; a second hardmask layer 344 comprising silicon nitride is formed over the pad oxide; a third hardmask layer 346 comprising silicon oxide is formed over the silicon nitride, and a fourth hardmask layer 348 comprising a-Si is disposed at the top of the stack. A purpose for an unexpected use of α-Si as part of a hardmask used to etch another α-Si layer is that this helps reduce ARDE, as explained in further detail below.

The hardmask layers may be deposited using, for example, chemical vapor deposition (CVD) or plasma enhanced chemical vapor deposition (PECVD). A patterned resist mask may be formed over the deposited fourth hardmask layer 348 using lithography, for example, EUV lithography, and the resist pattern may be transferred to the hardmask layers using, for example, anisotropic RIE to form the patterned etch mask 340.

The etch mask 340 in FIG. 3 is a pattern of features separated by a pattern of trenches 350. Since the pattern is subsequently transferred to the α-Si layer 310, the lateral dimensions in the pattern of trenches 350 in the etch mask 340 has to be the same as specified in the layout for patterning the α-Si layer 310. As mentioned above, the trench openings are distributed over a range having a minimum opening, sₘᵢₙ, and a maximum opening, sₘₐₓ. In FIG. 3, a wide trench 350A has the maximum opening, sₘₐₓ, and the narrow trench 350B has the minimum opening, sₘᵢₙ.

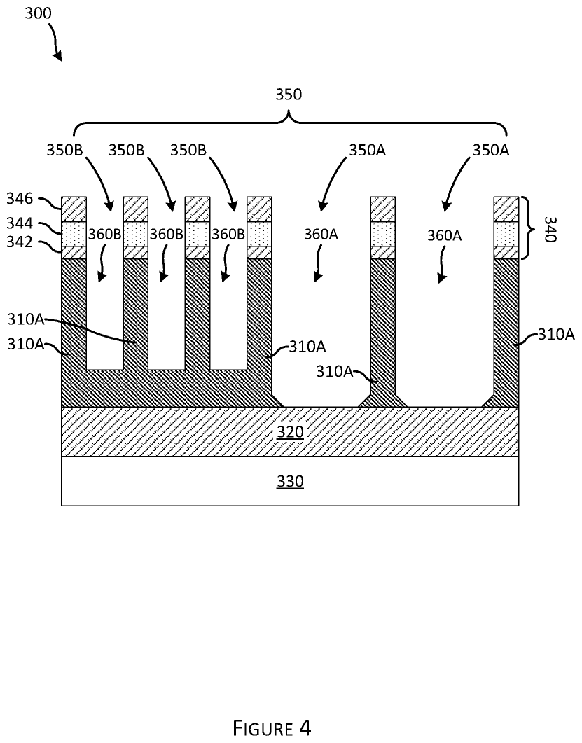

As illustrated in FIG. 4 and indicated in box 220 of the method 200 in FIG. 2, after forming the etch mask 340, a first process recipe is executed for a first duration to anisotropically etch a portion of the α-Si layer 310 (see FIG. 3) to form an upper portion of the α-Si features 310A. The trenches between adjacent α-Si features 310A include low-AR trenches 360A (with the wide opening, sₘₐₓ) and high-AR trenches 360B (with the narrow opening sₘᵢₙ). The first process recipe is for performing anisotropic etching without applying ARDP. Thus, the structure of substrate 300 at the end of this etch step exhibits the ARDE effect, as discussed below.

In some embodiments, executing the first recipe comprises exposing the substrate 300 to plasma generated in a plasma chamber using a mixture comprising chlorine (Cl₂), hydrogen bromide (HBr), and oxygen (O₂), as process gases and an inert gas as a carrier gas. The inert gas may be nitrogen, argon, helium, or the like. The first recipe may use a gas mixture with a low oxygen content. The gases containing halogens are the etchants, while a small amount of oxygen helps passivate sidewalls to get a more vertical side profile. The oxygen provides oxygen radicals that participate in oxidizing reactions, which produce oxygen-containing etch byproducts that are more resistant to etch than non-oxidized byproducts. The etch byproducts tend to coat the sidewalls, which helps to improve the selectivity with which material is removed from the trench bottom relative to the sidewalls. The flow rate for O₂ is low relative to the flow rate of etchants (Cl₂ and HBr). In some embodiments, in the first recipe, the flow rate for O₂ is about 20 sccm to about 65 sccm, while the flow rates for Cl₂ and HBr are about 90 sccm to about 240 sccm and about 130 sccm to about 360 sccm, respectively. In one embodiment, the flow rate for O₂ is about 35-40 sccm, while the flow rates for Cl₂ and HBr are about 145 sccm and about 215 sccm, respectively. In some embodiments, in the first recipe, a ratio of the flow rate for O₂ relative to the flow rate of etchants (Cl₂ and HBr) may be about 5% to about 20% and about 10% in one embodiment. In some embodiments, the inert gas nitrogen (N₂) is used with a flow rate of about 60 sccm to about 160 sccm and about 100 sccm in one embodiment. In some embodiments, the first recipe applies pulsed high frequency radio frequency (RF) source power in a range of about 480 W to about 1.3 kW and about 800 W in one embodiment. In some embodiments, a lower frequency pulsed RF bias power of about 480 W to about 1.3 kW and about 800 W in one embodiment may be applied. The plasma chamber may be at a controlled intermediate pressure of about 45 mTorr to about 130 mTorr and about 80 mTorr in one embodiment.

In this example embodiment, the first etch step (using the first recipe) is intended to remove a portion of the α-Si layer 310 till the underlying layer 320 is exposed at the bottom of the low-AR trenches 360A, leaving at most a small foot-shaped ring of α-Si feature 310A covering the underlying layer 320 along the periphery of the bottom of the low-AR trenches 360A. As mentioned above and explained in further detail below, the first duration has been tuned such that the edges of the low-AR trenches 360A are barely exposed, i.e., no more than just exposing the bottom corners. The first duration depends on the etch rate in the low-AR trenches 360A and the thickness, h, of the α-Si layer 310 being etched. Since there is no ARDP applied in the first duration, if the periphery of the bottom of the low-AR trench 360A is exposed then, in the absence of passivation, material would continue to be removed around the periphery to form notch defects. This underscores the importance of timely termination of the first recipe and initiation of ARDP using a second recipe.

The cross-sectional view in FIG. 4 illustrates the substrate 300 at the end of the first duration. The end of the first duration is the juncture at which the step for anisotropic etching with

ARDP is initiated, i.e., a second etch step using the second recipe. It is noted that the underlying layer 320 has been exposed from a central region at the bottom of the low-AR trenches to almost all the way to the corners, while the underlying layer 320 below the high-AR trenches remain covered, indicating that there is a significant ARDE effect for this step of the etch process. Once the periphery of the bottom of the low-AR trench 360A is exposed the ARDE effect is countered by applying ARDP using a second recipe (described in further detail below).

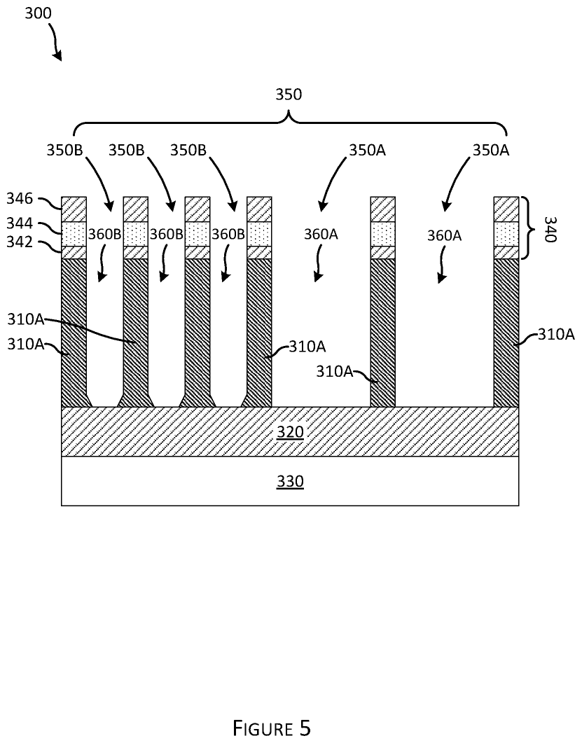

At the end of the first duration, the second etch step, which comprises concurrent anisotropic etching and ARDP, is applied for a second duration using the second recipe. As illustrated in FIG. 5, with ARDP applied, the bottom edges and corners of the low-AR trenches 360A are protected while the high-AR trenches 360B can be etched further to bring the trench depth there close to target. Once the removal of a-Si (from the a-Si features 310A) is arrested in the low-AR trench 360A by ARDP, the second recipe etches the high-AR trenches 360B at a higher rate relative to the low-AR trenches 360A. In other words, in the second duration, the high-AR trenches 360B are etched selective to the low-AR trenches 360A.

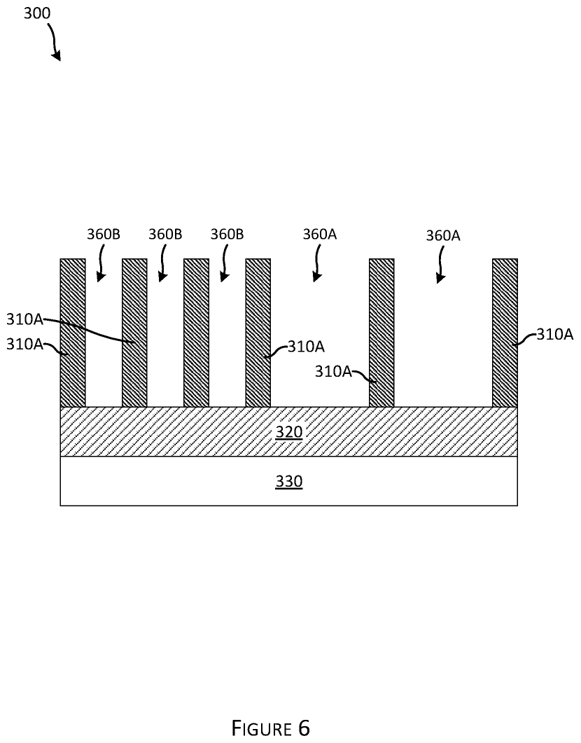

As illustrated in FIG. 6, after the second duration, an overetch step is performed with an overetch recipe (described in detail further below) to complete etching the high-AR trenches 360B and forming the α-Si features 310A. The halogens and halogen-containing gases provide etchants to remove silicon from the α-Si layer 310 by chemical reactions that produce volatile byproducts. The anisotropy of the etch process is typically achieved by applying low-frequency RF bias and/or DC bias to direct an ion flux in the vertical direction, thereby suppressing etching the sides laterally.

The oxygen radicals in the plasma participate in oxidizing chemical reactions resulting in deposition of silicon oxide (SiO)₂) and formation of etch byproducts containing oxygen such as SiOHCl, SiOHBr, silicon oxychloride (SiOCl), and silicon oxybromide (SiOBr). Such oxygen-containing compounds may stick to and passivate exposed silicon surfaces. Other byproducts include silicon chloride (SiCl₃), silicon bromide (SiBrₓ), which are relatively more volatile, hence less effective in passivating silicon surfaces. The passivation occurs predominantly on the sides because the bottom surface is bombarded by energetic ions that sputter away etch byproducts and oxidized silicon. The preferential sidewall passivation is instrumental in the etch process being anisotropic and preferentially removing material from horizontal surfaces.

The low oxygen content in the first recipe allows the etching of the α-Si layer 310 to proceed rapidly in the absence of any significant amount of passivating byproducts or oxidation of silicon. Because of the narrow openings, the high-AR trenches 360B are starved of etchants relative to the wide low-AR trenches 360A, resulting in ARDE. As seen in FIG. 4, by the end of the first duration, the fourth hardmask layer 348 is completely removed. Nevertheless, some oxygen consumption may occur in the first hardmask layer 342 and third hardmask layer 346, i.e., in the silicon oxide, and in the second hardmask layer 344, i.e., in the silicon nitride.

At the end of the first duration, the second recipe is executed for a second duration in situ in the plasma chamber as indicated in box 230 of the flowchart for method 200, illustrated in FIG. 2. A transition from the first recipe to the second recipe is achieved by increasing the ratio of the flow rate for O₂ relative to the flow rate of etchants (Cl₂ and HBr) and by lowering the pressure in the chamber. The higher oxygen to etchant ratio and lower pressure results in passivating byproducts being deposited on exposed sides of the α-Si features 310A, illustrated in FIG. 4. Thus, the second duration may be referred to as a passivation duration, in this disclosure. As explained above, a coating of oxygen-containing byproducts, such as silicon oxide (SiO₂), silicon chloride (SiCl), silicon bromide (SiBrₓ), SiOHCl, SiOHBr, silicon oxychloride (SiOCl), and silicon oxybromide (SiOBr), passivate the surfaces over which the coating is formed. In both low AR trenches 360A and high-AR trenches 360B, etching may generate byproducts. However, the deposition rate of oxygen-containing passivation byproducts is higher in the low-AR trenches 360A relative to that in the high-AR trenches 360B. This may occur because the supply of oxygen is more limited in the high-AR trenches 360B than in the low-AR trenches 360A. Additionally, the consumption of oxygen by the etch mask 340 (e.g., by the α-Si in the fourth hardmask layer 348) further reduces oxygen entering the narrow openings 350B. Therefore, in the low-AR trenches 360A, etching is suppressed, whereas, in high-AR trenches 360B, etching may proceed.

The flow rate of oxygen is high in the second recipe relative to the flow rate of etchants (Cl₂ and HBr). In some embodiments, in the second recipe, the flow rate for O₂ is about 10 sccm to about 40 sccm, while the flow rates for Cl₂ and HBr are about 15 sccm to about 50 sccm and 5 sccm to about 20 sccm, respectively. In one embodiment, the flow rate for O₂ is about 20-25 sccm, while the flow rates for Cl₂ and HBr are about 30 sccm and about 10 sccm, respectively. In some embodiments, in the second recipe, a ratio of the flow rate for O₂ relative to the flow rate of etchants (Cl₂ and HBr) may be about 45% to about 65% and about 55% in one embodiment. In some embodiments, the inert gas argon (Ar) is used with a flow rate of about 150 sccm to about 500 sccm and about 300 sccm in one embodiment.

In some embodiments, the second recipe applies high frequency RF source power in a range of about 100 W to about 250 W and about 160 W in one embodiment. In some embodiments, a lower frequency RF bias power of about 60 W to about 170 W and about 100 W in one embodiment may be applied. The plasma chamber may be at a controlled low pressure of about 5 mTorr to about 20 mTorr in one embodiment.

The higher oxygen in the plasma composition of the second etch step enhances the oxidation of silicon and passivation by oxygen-containing etch byproducts, as described above. The passivation slows down the removal rate of silicon by the etchants (i.e., the halogens). As in the case of etchants, it is also difficult for oxygen radicals to reach a bottom surface of the high-AR trenches 360B relative to the much wider low-AR trenches 360A. The process parameters and the mask materials have been selected so the passivation occurs preferentially in the low-AR trenches 360A. Anisotropic etching continues but, as a result of ARDP, the ARDE effect is reversed and the removal rate is now higher in the high-AR trenches 360B relative to the passivated low-AR trenches 360A.

FIG. 5 illustrates a cross-sectional view of the substrate 300 at the end of the second duration, the duration when ARDP is applied while anisotropic etching progresses with a higher etch rate in the high-AR trenches 360B. In FIG. 5, the second duration has been adjusted to expose the underlying layer 320 at the bottom of the high-AR trenches 360B. At the same time, the second etch step removes any residual footing at the base of the sides of low-AR trenches 360A. In various embodiments, the second duration may be from about 5 s to about 20 s and about 10 s in one embodiment to obtain a vertical side profile in the low-AR trench 360A.

It is noted that the inventors have verified through controlled experimentation, that if ARDP is applied too early, which implies that the first duration was terminated prematurely, then the low-AR trenches 360A are likely to have notching defects since the corner had not been exposed during the second etch step with the second recipe when the passivating etch byproducts are deposited. Thus, the periphery of the bottom of the low-AR trenches 360A will not be protected during the overetch step that is performed after etching with the second recipe is terminated at the end of the second duration. The unprotected edges at the bottom of the low-AR trenches 360A are susceptible to notching defects. If the ARDP is applied too late, which implies that the first duration was excessively long then too the low-AR trenches 360A are likely to have notch defects because the low-AR trenches 360A would start to notch before any protection is applied. That is, the first recipe may have already removed the desired amount of material and exposed the periphery of the bottom of the low-AR trenches 360A prior to passivation. Without adequate passivation, further etching results in the formation of notch defects.

At the end of the second duration, there may be a small foot remaining in the high-AR trenches 360B, as seen in the cross-sectional view illustrated in FIG. 5. The purpose of the overetch step is to trim this foot. As indicated in box 240 of the flowchart for the method 200, illustrated in FIG. 2, an overetch recipe may be executed for an overetch duration to remove the foot defects seen in the high-AR trenches 360B. ARDP is not applied during the overetch step. The overetch recipe may differ from the first recipe. The overetch recipe uses high etchant flow (Cl₂ and HBr) with low oxygen flow. The chamber pressure may be relatively high. While the source power may be pulsed RF power, continuous wave (CW) RF bias power may be used. The etch rate can be modulated by the RF bias power. The overetch duration may be adjusted to obtain a vertical side profile for the sides of the high-AR trenches 360B. In various embodiments, the overetch duration may be from about 1 minute to about 10 minutes and about 6 minutes in one embodiment.

In some embodiments, in the overetch recipe, the flow rate for O₂ is about 10 sccm to about 40 sccm, while the flow rate for HBr is about 350 sccm to about 1000 sccm. In one embodiment, the flow rate for O₂ is about 20 sccm, while the flow rate for HBr is about 600 sccm. (Chlorine is not used in this example overetch recipe.) In some embodiments, in the overetch recipe, a ratio of the flow rate for O₂ relative to the flow rate of etchants (Cl₂ and HBr) may be about 2% to about 6% and about 3-5% in one embodiment. In some embodiments, the inert gas argon (Ar) is used with a flow rate of about 300 sccm to about 800 sccm and about 500 sccm in one embodiment.

In some embodiments, the overetch recipe applies pulsed high frequency RF source power in a range of about 180 W to about 500 W and about 300 W in one embodiment. In some embodiments, a lower frequency RF bias power of about 360 W to about 1 kW and about 600 W in one embodiment may be applied. The plasma chamber may be at a controlled intermediate pressure of about 50 mTorr to about 150 mTorr and about 100-125 mTorr in one embodiment.

In various embodiments, the high frequency RF source power and the lower frequency RF bias power may be RF signals having a pulsed RF waveform or a CW RF waveform.

FIG. 6 illustrates a cross-sectional view of the substrate 300 after the overetch step is completed and the etch mask is removed. As desired, the foot defects at the base of the high-AR trenches 360B have been removed to produce vertical side profiles. The sides of the low-AR trenches 360A, being protected by passivating etch byproducts, are also vertical.

The example embodiment is described for a specific set of material layers, processing chemicals, and process parameters for the sake of specificity only. The inventive aspects of this example may be adapted to other materials and processes by a person skilled in the art.

The example method 200 described above with reference to the flowchart illustrated in FIG. 2 and the cross-sectional views of a substrate 300 in FIGS. 3-6, has incorporated a single ARDP and concurrent anisotropic etch step in a multi-step etch process for patterning features in a layer separated by a pattern of trenches having various ARs and trench openings over predefined ranges of trench opening and AR. The method 200 provides the advantage of forming features with vertical sides that are free of foot and notch defects.

It is understood that similar etch processes may be devised incorporating multiple ARDP and concurrent etching steps. Likewise, it is understood that adaptive ARDP and concurrent etching may be performed where the passivation rate and the aspect ratio dependence of passivation may be adjusted dynamically by dynamically adjusting relevant process parameters such as the oxygen content in the composition of plasma. In the example embodiment, the concurrent ARDP and etching technique has been utilized for an application where the trenches are formed extending through the layer being etched. However, it is understood that a similar method incorporating the concurrent ARDP and etching technique may be utilized to improve trench depth uniformity for an application where the trenches are formed extending partially through the layer being etched.

Example embodiments of the invention are summarized here. Other embodiments can also be understood from the entirety of the specification as well as the claims filed herein.

Example 1. A method for fabricating a semiconductor device, the method including: forming a pattern of trenches by etching a first layer formed over an underlying layer of a substrate, each of the trenches having an aspect ratio (AR) in a range with a lower limit of a first AR and an upper limit of a second AR, the pattern including a low-AR trench having the first AR and a high-AR trench having the second AR, the AR of a trench being a ratio of its depth to its opening, the etching including: executing a first recipe in a plasma chamber to anisotropically etch the first layer for a first duration by flowing etchants through the chamber, an etch rate of the first layer being higher on the low-AR trench relative to that on the high-AR trench; and after executing the first recipe, executing a second recipe in the plasma chamber to etch the first layer anisotropically and concurrently deposit oxygen-containing etch byproducts to passivate exposed portions of sides of the trenches, the etch rate of the first layer being lower on the low-AR trench relative to that on the high-AR trench, wherein executing the second recipe increases a relative oxygen content in the plasma chamber from a first value during the executing of the first recipe to a second value.

Example 2. The method of example 1, where executing the first recipe includes exposing the substrate to plasma including halogens, hydrogen, oxygen, and an inert species.

Example 3. The method of one of examples 1 or 2, where executing the first recipe includes maintaining a chamber pressure of the plasma chamber at a first chamber pressure, and where executing the second recipe includes maintaining a chamber pressure of the plasma chamber at a second chamber pressure, the second chamber pressure being lower than the first chamber pressure.

Example 4. The method of one of examples 1 to 3, where executing the first recipe includes maintaining a ratio of a flow rate of etchants to a flow rate of oxygen to a first ratio, and where executing the second recipe includes maintaining a ratio of a flow rate of etchants to a flow rate of oxygen to a second ratio, the second ratio being lower than the first ratio.

Example 5. The method of one of examples 1 to 4, further including: terminating the execution of the second recipe after a predetermined second duration, where the second duration is configured to produce, at the end of the second duration, an exposed portion of a surface of the underlying layer in the high-AR trench, and where the first duration is configured to produce, at the end of the first duration, an exposed portion of a surface of the underlying layer in the low-AR trench.

Example 6. The method of one of examples 1 to 5, where the etching further includes: after executing the second recipe, executing an overetch recipe in the plasma chamber to remove material from the first layer for an overetch duration.

Example 7. The method of one of examples 1 to 6, where executing the first recipe includes powering a plasma in the plasma chamber with a first radio frequency (RF) bias signal that is pulsed RF signal, and where executing the overetch recipe includes powering the plasma in the plasma chamber with an overetch radio frequency (RF) bias signal that is a continuous wave RF signal.

Example 8. The method of one of examples 1 to 7, where executing the first recipe includes flowing etchants at a first flow rate, and maintaining a chamber pressure of the plasma chamber at a first chamber pressure; and where executing the overetch recipe includes flowing etchants at an overetch flow rate, and maintaining a chamber pressure of the plasma chamber at a overetch chamber pressure, where the overetch flow rate is higher than the first flow rate, and where the overetch chamber pressure is higher than first chamber pressure.

Example 9. The method of one of examples 1 to 8, where the overetch duration is configured to expose a surface of the underlying layer and produce a vertical side profile with no footing proximate a base of the high-AR trench.

Example 10. The method of one of examples 1 to 9, where a ratio of the second AR to the first AR is greater than 16 and less than 100.

Example 11. A method for fabricating a semiconductor device, the method including: in a plasma chamber, anisotropically etching a silicon layer formed over an underlying layer of a substrate through an etch mask to form features having a plurality of sides with vertical side profiles, the plurality of sides including a first side with a first aspect ratio (AR) and a second side with a second AR higher than the first AR, the etching including: forming an upper portion of the features by exposing the substrate, for a first duration, to plasma generated using chlorine, hydrogen bromide, oxygen, and an inert gas; and at the end of the first duration, performing, for a second duration, an aspect ratio dependent passivation (ARDP) while etching the silicon layer, the etching of the silicon layer during the second duration being slower on the first side than on the second side, the performing including reducing a chamber pressure, reducing a ratio of a flow rate of etchants to a flow rate of oxygen, the etchants being chlorine and hydrogen bromide, and, where, during the performing, oxygen-containing etch byproducts are deposited to passivate exposed portions of the sides, the deposition being faster on the first side than on the second side.

Example 12. The method of example 11, where the first AR is greater than 0.15 and less than 3, and the second AR is greater than 5 and less than 15.

Example 13. The method of one of examples 11 or 12, where each side of the plurality of sides characterized by an aspect ratio (AR), h/s, s being a space between the side and an adjacent side and h being a height of the side, and where h is greater than 150 nm and less than 450 nm.

Example 14. The method of one of examples 11 to 13, where the oxygen-containing etch byproducts deposited while performing the ARDP are materials containing O and Si, in combination with H, Br, or Cl, including silicon oxide (SiO2), SiOHCl, SiOHBr, silicon oxychloride (SiOCl), and silicon oxybromide (SiOBr).

Example 15. The method of one of examples 11 to 14, where the etching further includes: at the end of the second duration, performing an overetch step for an overetch duration, where performing the overetch step includes increasing the chamber pressure, increasing the ratio of the flow rate of etchants to the flow rate of oxygen, the second duration being configured to form a vertical side profile for the first side, and the overetch duration being configured to form a vertical side profile for the second side.

Example 16. The method of one of examples 11 to 15,where, after performing the overetch step, the first side and the second side are devoid of foot and notch defects and a portion of the underlying layer between sides of adjacent features is exposed.

Example 17. The method of one of examples 11 to 16, where each side of the plurality of sides characterized by an aspect ratio (AR), h/s, s being a space between the side and an adjacent side and h being a height of the side, and where, a ratio of h to a height of the etch mask is from about 3 to about 10.

Example 18. The method of one of examples 11 to 17, where the etch mask includes a stack of layers, the stack including a first hardmask layer including silicon oxide formed over the silicon layer, a second hardmask layer including silicon nitride formed over the first hardmask layer, a third hardmask layer including silicon oxide formed over the second hardmask layer, and a fourth hardmask layer including silicon formed over the third hardmask layer, the fourth hardmask layer being removed during etching the silicon layer.

Example 19. A method for forming a pattern of features in a first layer of a substrate, the method including: forming, over the first layer, an etch mask having a two-dimensional (2D) layout geometrically identical to the pattern of features, the features being separated from each other by one of a plurality of trenches, the plurality of trenches including a low aspect ratio (low-AR) trench and a high aspect ratio (high-AR) trench; using the etch mask, anisotropically etching an upper portion of the first layer for a first duration to form upper portions of the features and the plurality of trenches, the first duration being configured to expose a portion of a surface of an underlying layer at the bottom of the low-AR trench, the underlying layer being disposed adjacent below the first layer; and performing, over a passivation duration, an aspect ratio dependent passivation (ARDP) while anisotropically etching a lower portion of the first layer, the passivation being faster in the low-AR trench relative to the high-AR trench, the etching of the lower portion of the first layer being slower in the low-AR trench relative to the high-AR trench, the passivation duration being configured to form a vertical side profile proximate a base of the low-AR trench and to expose a portion of a surface of the underlying layer at the bottom of the high-AR trench.

Example 20. The method of example 19, further including: after performing the ARDP, performing an overetch step for an overetch duration, the overetch duration being configured to form a vertical side profile proximate a base of the high-AR trench.

Example 21. The method of one of examples 19 or 20, where anisotropically etching an upper portion of the first layer includes executing, in a plasma chamber, a first recipe, where the first recipe specifies a first ratio of a gas flow rate of etchants to a gas flow rate of oxygen, a first pressure of gas in the plasma chamber, and a pulsed radio frequency (RF) bias signal; and performing an aspect ratio dependent passivation (ARDP) while anisotropically etching a lower portion of the first layer includes executing, in situ in the plasma chamber, a second recipe, where the second recipe specifies a second ratio of a gas flow rate of etchants to a gas flow rate of oxygen, and a second pressure of gas in the plasma chamber, the second ratio being lower than the first ratio and the second pressure being lower than the first pressure.

Example 22. The method of one of examples 19 to 21, further including performing an overetch step for an overetch duration after performing the ARDP, where performing the overetch step includes executing, in a plasma chamber, an overetch recipe, where the overetch recipe specifies a third ratio of a gas flow rate of etchants to a gas flow rate of oxygen, a third pressure of gas in the plasma chamber, and a continuous wave RF bias signal, the third ratio being higher than the first ratio and the third pressure being higher than the first pressure.

Example 23. The method of one of examples 19 to 22, where, during performing the ARDP, etch byproducts are deposited on exposed portions of the sides of the plurality of trenches, the deposition of the etch byproducts being faster in the low-AR trench than in the high-AR trench.

Example 24. The method of one of examples 19 to 23, each feature having a height, h, equal to a thickness of the first layer, each trench of the plurality of trenches having an opening, s, and an aspect ratio (AR) of h/s, and where s is in a range from sₘᵢₙ to sₘₐₓ, sₘₐₓ being greater than sₘᵢₙ, the etch mask including a geometry with an opening of sₘₐₓ and a different geometry with an opening of s to form, in the first layer, a low-AR trench with AR of h/sₘₐₓ and a high-AR trench with AR of h/sₘᵢₙ, respectively where sₘᵢₙ is between 10 nm and 30 nm, and where sₘₐₓ is greater than 16 times sₘᵢₙ and less than 100 times sₘᵢₙ.

Example 25. The method of one of examples 19 to 24, where h is greater than 150 nm and less than 450 nm.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for fabricating a semiconductor device, the method comprising:
forming a pattern of trenches by etching a first layer formed over an underlying layer of a substrate, each of the trenches having an aspect ratio (AR) in a range with a lower limit of a first AR and an upper limit of a second AR, the pattern including a low-AR trench having the first AR and a high-AR trench having the second AR, the AR of a trench being a ratio of its depth to its opening width, the etching comprising:
executing a first recipe in a plasma chamber to anisotropically etch the first layer for a first duration by flowing etchants through the chamber, an etch rate of the first layer being higher on the low-AR trench relative to that on the high-AR trench; and
after executing the first recipe, executing a second recipe in the plasma chamber to etch the first layer anisotropically and concurrently deposit oxygen-containing etch byproducts to passivate exposed portions of sides of the trenches, the etch rate of the first layer being lower on the low-AR trench relative to that on the high-AR trench, wherein executing the second recipe increases a relative oxygen content in the plasma chamber from a first value during the executing of the first recipe to a second value.

2. The method of claim 1, wherein executing the first recipe comprises exposing the substrate to plasma comprising halogens, hydrogen, oxygen, and an inert species.

3. The method of claim 1,
wherein executing the first recipe comprises maintaining a chamber pressure of the plasma chamber at a first chamber pressure, and
wherein executing the second recipe comprises maintaining a chamber pressure of the plasma chamber at a second chamber pressure, the second chamber pressure being lower than the first chamber pressure.

4. The method of claim 1,
wherein executing the first recipe comprises maintaining a ratio of a flow rate of etchants to a flow rate of oxygen to a first ratio, and
wherein executing the second recipe comprises maintaining a ratio of a flow rate of etchants to a flow rate of oxygen to a second ratio, the second ratio being lower than the first ratio.

5. The method of claim 1, further comprising:
terminating the execution of the second recipe after a predetermined second duration, wherein the second duration is configured to produce, at the end of the second duration, an exposed portion of a surface of the underlying layer in the high-AR trench, and
wherein the first duration is configured to produce, at the end of the first duration, an exposed portion of a surface of the underlying layer in the low-AR trench.

6. The method of claim 1, wherein the etching further comprises:
after executing the second recipe, executing an overetch recipe in the plasma chamber to remove material from the first layer for an overetch duration.

7. The method of claim 6, wherein executing the first recipe comprises powering a plasma in the plasma chamber with a first radio frequency (RF) bias signal that is pulsed RF signal, and
wherein executing the overetch recipe comprises powering the plasma in the plasma chamber with an overetch radio frequency (RF) bias signal that is a continuous wave RF signal.

8. The method of claim 6,
wherein executing the first recipe comprises
flowing etchants at a first flow rate, and maintaining a chamber pressure of the plasma chamber at a first chamber pressure; and
wherein executing the overetch recipe comprises
flowing etchants at an overetch flow rate, and maintaining a chamber pressure of the plasma chamber at a overetch chamber pressure, wherein the overetch flow rate is higher than the first flow rate, and wherein the overetch chamber pressure is higher than first chamber pressure.

9. The method of claim 6, wherein the overetch duration is configured to expose a surface of the underlying layer and produce a vertical side profile with no footing proximate a base of the high-AR trench.

10. A method for fabricating a semiconductor device, the method comprising:
in a plasma chamber, anisotropically etching a silicon layer formed over an underlying layer of a substrate through an etch mask to form features comprising a plurality of sides with vertical side profiles, the plurality of sides including a first side with a first aspect ratio (AR) and a second side with a second AR higher than the first AR, the etching comprising:
forming an upper portion of the features by exposing the substrate, for a first duration, to plasma generated with chlorine, hydrogen bromide, oxygen, and an inert gas; and
at the end of the first duration, performing, for a second duration, an aspect ratio dependent passivation (ARDP) while etching the silicon layer, the etching of the silicon layer during the second duration being slower on the first side than on the second side, the performing comprising reducing a chamber pressure, reducing a ratio of a flow rate of etchants to a flow rate of oxygen, the etchants being chlorine and hydrogen bromide, and, wherein, during the performing, oxygen-containing etch byproducts are deposited to passivate exposed portions of the sides, the deposition being faster on the first side than on the second side.

11. The method of claim 10, wherein the oxygen-containing etch byproducts deposited while performing the ARDP are materials containing O and Si, in combination with H, Br, or Cl, including silicon oxide (SiO₂), SiOHCl, SiOHBr, silicon oxychloride (SiOCl), and silicon oxybromide (SiOBr).

12. The method of claim 10, wherein the etching further comprises:
at the end of the second duration, performing an overetch step for an overetch duration, wherein performing the overetch step comprises increasing the chamber pressure, increasing the ratio of the flow rate of etchants to the flow rate of oxygen, the second duration being configured to form a vertical side profile for the first side, and the overetch duration being configured to form a vertical side profile for the second side.

13. The method of claim 12, wherein, after performing the overetch step, the first side and the second side are devoid of foot and notch defects and a portion of the underlying layer between sides of adjacent features is exposed.

14. The method of claim 10, wherein the etch mask comprises a stack of layers, the stack comprising a first hardmask layer comprising silicon oxide formed over the silicon layer, a second hardmask layer comprising silicon nitride formed over the first hardmask layer, a third hardmask layer comprising silicon oxide formed over the second hardmask layer, and a fourth hardmask layer comprising silicon formed over the third hardmask layer, the fourth hardmask layer being removed during etching the silicon layer.

15. A method for forming a pattern of features in a first layer of a substrate, the method comprising:
forming, over the first layer, an etch mask having a two-dimensional (2D) layout geometrically identical to the pattern of features, the features being separated from each other by one of a plurality of trenches, the plurality of trenches comprising a low aspect ratio (low-AR) trench and a high aspect ratio (high-AR) trench;
using the etch mask, anisotropically etching an upper portion of the first layer for a first duration to form upper portions of the features and the plurality of trenches, the first duration being configured to expose a portion of a surface of an underlying layer at a bottom of the low-AR trench, the underlying layer being disposed adjacent below the first layer; and
performing, over a passivation duration, an aspect ratio dependent passivation (ARDP) while anisotropically etching a lower portion of the first layer, the passivation being faster in the low-AR trench relative to the high-AR trench, the etching of the lower portion of the first layer being slower in the low-AR trench relative to the high-AR trench, the passivation duration being configured to form a vertical side profile proximate a base of the low-AR trench and to expose a portion of a surface of the underlying layer at the bottom of the high-AR trench.

16. The method of claim 15, further comprising:
after performing the ARDP, performing an overetch step for an overetch duration, the overetch duration being configured to form a vertical side profile proximate a base of the high-AR trench.

17. The method of claim 15,
wherein anisotropically etching an upper portion of the first layer comprises executing, in a plasma chamber, a first recipe, wherein the first recipe specifies a first ratio of a gas flow rate of etchants to a gas flow rate of oxygen, a first pressure of gas in the plasma chamber, and a pulsed radio frequency (RF) bias signal; and
performing an aspect ratio dependent passivation (ARDP) while anisotropically etching a lower portion of the first layer comprises executing, in situ in the plasma chamber, a second recipe, wherein the second recipe specifies a second ratio of a gas flow rate of etchants to a gas flow rate of oxygen, and a second pressure of gas in the plasma chamber, the second ratio being lower than the first ratio and the second pressure being lower than the first pressure.

18. The method of claim 17, further comprising performing an overetch step for an overetch duration after performing the ARDP, wherein performing the overetch step comprises executing, in a plasma chamber, an overetch recipe, wherein the overetch recipe specifies a third ratio of a gas flow rate of etchants to a gas flow rate of oxygen, a third pressure of gas in the plasma chamber, and a continuous wave RF bias signal, the third ratio being higher than the first ratio and the third pressure being higher than the first pressure.

19. The method of claim 15, wherein, during performing the ARDP, etch byproducts are deposited on exposed portions of the sides of the plurality of trenches, the deposition of the etch byproducts being faster in the low-AR trench than in the high-AR trench.

20. The method of claim 15, wherein each trench of the plurality of trenches having an opening, s, and an aspect ratio (AR) of h/s, and wherein s being in a range from sₘᵢₙ to sₘₐₓ, sₘₐₓ being greater than sₘᵢₙ, the etch mask including a geometry with an opening of sₘₐₓ and a different geometry with an opening of sₘₐₓ to form, in the first layer, a low-AR trench with AR of h/sₘₐₓ and a high-AR trench with AR of h/sₘᵢₙ, respectively wherein sₘₐₓ is between 10 nm and 30 nm, and wherein s is greater than 16 times sₘᵢₙ and less than 100 times sₘᵢₙ.
